(19) United States
(12) Patent Application Publication
(10) Pub. No.: US 2024/0243703 A1
(43) Pub. Date: Jul. 18, 2024

(54) POWER AMPLIFYING DEVICE

(71) Applicant: Murata Manufacturing Co., Ltd., Kyoto (JP)

(72) Inventor: Yusaku KOMAMURA, Kyoto (JP)

(21) Appl. No.: 18/500,417

(22) Filed: Nov. 2, 2023

(30) Foreign Application Priority Data
Jan. 17, 2023 (JP) 2023-005186

(51) Int. Cl. H03F 1/30; H03F 3/217

(52) U.S. Cl. CPC H03F 1/30; H03F 3/2171; H03F 2200/451; H03F 2203/21103; H03F 2203/21139

(57) ABSTRACT

A power amplifying device includes first unit transistors and second unit transistors. The first unit transistors are connected in parallel and configured to amplify a radio frequency signal and to output a resultant signal. The second unit transistors are connected in parallel and configured to amplify the signal output by the first unit transistors and to output a resultant signal. Each of the first unit transistors is smaller than each of the second unit transistors.

### CROSS REFERENCE TO RELATED APPLICATION

This application claims priority from Japanese Patent Application No. 2023-005186 filed on Jan. 17, 2023. The content of this application is incorporated herein by reference in its entirety.

### BACKGROUND ART

The present disclosure relates to a power amplifying device.

A known radio-frequency power amplifier circuit includes amplification stages and an impedance matching circuit connected between the amplification stages (see, for example, Japanese Unexamined Patent Application Publication No. 2007-150676).

As the first amplification stage and the final amplification stage, field-effect transistors (FETs) are included in the radio-frequency amplifier circuit described in Japanese Unexamined Patent Application Publication No. 2007-150676, in which no mention is made of how to dissipate heat generated in the FETs. The generation of high-power amplified signals involves rises in the temperature of the FETs. Consequently, the gain of the FETs and/or the reliability of the integrated circuit can be impaired.

### BRIEF SUMMARY

The present disclosure provides a power amplifying device that is operable without necessarily significant deterioration of amplification characteristics and without necessarily significant impairment of reliability and that is compact in size.

A power amplifying device according to an aspect of the present disclosure includes first unit transistors and second unit transistors. The first unit transistors are connected in parallel and configured to amplify a radio frequency signal and to output a resultant signal. The second unit transistors are connected in parallel and configured to amplify the signal output by the first unit transistors and to output a resultant signal. Each of the first unit transistors is smaller than each of the second unit transistors.

The present disclosure can provide a power amplifying device that is operable without necessarily significant deterioration of amplification characteristics and without necessarily significant impairment of reliability and that is compact in size.

### BRIEF DESCRIPTION OF THE DRAWINGS

FIG. 1 is a circuit diagram of a power amplifier circuit 101;

FIG. 2 is a schematic sectional view of a power amplifying device 11 taken along a line parallel to the yz-plane;

FIG. 3 is a plan view of a semiconductor chip 211 included in the power amplifying device 11, illustrating the semiconductor chip 211 viewed from the above;

FIG. 4 is an enlarged plan view of a unit transistor 251, illustrating the unit transistor 251 viewed from the above;

FIG. 5 is an enlarged plan view of a unit transistor 251a, namely, a first modification of the unit transistor 251, illustrating the unit transistor 251a viewed from the above;

FIG. 6 is an enlarged plan view of a unit transistor 251b, namely, a second modification of the unit transistor 251, illustrating the unit transistor 251b viewed from the above;

FIG. 7 is an enlarged plan view of a unit transistor 251c, namely, a third modification of the unit transistor 251, illustrating the unit transistor 251c viewed from the above;

FIG. 8 is a schematic sectional view of a power amplifying device 12 taken along a line parallel to the yz-plane;

FIG. 9 is a plan view of a semiconductor chip 211 included in the power amplifying device 12, illustrating the semiconductor chip 211 viewed from the above;

FIG. 10 is a plan view of a semiconductor chip 211 included in a power amplifying device 13, illustrating the semiconductor chip 211 viewed from the above; and

FIG. 11 is a plan view of a semiconductor chip 211 included in a power amplifying device 14, illustrating the semiconductor chip 211 viewed from the above.

### DETAILED DESCRIPTION

Embodiments of the present disclosure are described below in detail with reference to the accompanying drawings. Redundant description of the same constituent components, which are denoted by the same reference signs, will be omitted wherever possible.

### First Embodiment

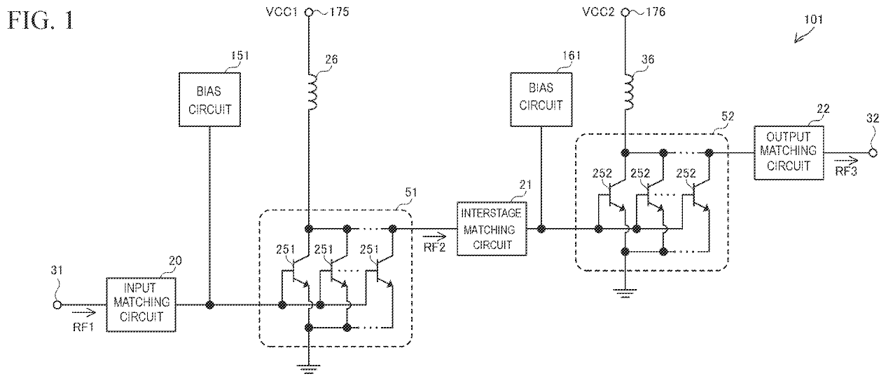

The following describes a power amplifier circuit 101 and a power amplifying device 11 according to a first embodiment. FIG. 1 is a circuit diagram of the power amplifier circuit 101. Referring to FIG. 1, the power amplifier circuit 101 is a two-stage amplifier circuit configured to amplify a signal RF1 input through an input terminal 31 and to output an amplified signal RF3 through an output terminal 32. For example, the signal RF1 is a radio frequency signal. An antenna or any other load (not illustrated) is connected to the output of the power amplifier circuit 101 or, more specifically, to the output terminal 32.

The power amplifier circuit 101 includes an input matching circuit 20, an interstage matching circuit 21, an output matching circuit 22, an inductor 26, an inductor 36, a driver-stage amplifier 51, a power-stage amplifier 52, a driver-stage bias supply circuit 151, and a power-stage bias supply circuit 161.

The driver-stage amplifier 51 includes unit transistors 251 (first unit transistors), which are connected in parallel. The power-stage amplifier 52 includes unit transistors 252 (second unit transistors), which are connected in parallel. The unit transistors 251 may be, but are not necessarily, equal in number to the unit transistors 252.

The transistors (e.g., the unit transistors 251 and the unit transistors 252) in the present embodiment may for example, be bipolar transistors, such as heterojunction bipolar transistors (HBTs). It is not required that the transistors be HBTs. In some embodiments, the transistors are metal-oxide-semiconductor field-effect transistors (MOSFETs). If this is the case, “base”, “collector”, and “emitter” shall be read as “gate”, “drain”, and “source”, respectively.

The unit transistors 251 included in the driver-stage amplifier 51 amplify the signal RF1 input through the input terminal 31 and transmitted through the input matching circuit 20. The unit transistors 251 then output the resultant signal, namely, an amplified signal RF2.

More specifically, the input matching circuit 20 is disposed between the input terminal 31 and the driver-stage amplifier 51 and provides impedance matching between a circuit (not illustrated) preceding the input terminal 31 and the driver-stage amplifier 51.

A power supply voltage VCC1 for effecting the operation of the unit transistors 251 included in the driver-stage amplifier 51 is supplied through a power-supply voltage supply terminal 175.

The unit transistors 251 are each connected to the power-supply voltage supply terminal 175 with the inductor 26 therebetween and each include a collector connected to an input terminal of the interstage matching circuit 21, a base connected to the input terminal 31 with the input matching circuit 20 therebetween, and an emitter connected to the ground.

To put it more concretely, the bases of the unit transistors 251 included in the driver-stage amplifier 51 are connected to each other and connected to the input terminal 31 (or the input of the driver-stage amplifier 51). The collectors of the unit transistors 251 included in the driver-stage amplifier 51 are connected to each other and connected to the input terminal of the interstage matching circuit 21 (or the output of the driver-stage amplifier 51). The emitters of the unit transistors 251 included in the driver-stage amplifier 51 are connected to each other and connected to the ground. This means that the unit transistors 251 are connected in parallel.

The driver-stage bias supply circuit 151 provides bias to the bases of the unit transistors 251 included in the driver-stage amplifier 51. More specifically, the driver-stage bias supply circuit 151 provides bias for class-A operation of the unit transistors 251.

The interstage matching circuit 21 includes an input terminal connected to the output of the driver-stage amplifier 51 and an output terminal connected to the input of the power-stage amplifier 52 and provides impedance matching between the driver-stage amplifier 51 and the power-stage amplifier 52.

The unit transistors 252 included in the power-stage amplifier 52 amplify the amplified signal RF2 (output signal) supplied by the driver-stage amplifier 51 and transmitted through the interstage matching circuit 21. The unit transistors 252 then output the resultant signal, namely, an amplified signal RF3 to the output terminal 32 through the output matching circuit 22.

A power supply voltage VCC2 for effecting the operation of the unit transistors 252 included in the power-stage amplifier 52 is supplied through a power-supply voltage supply terminal 176.

The unit transistors 252 are each connected to the power-supply voltage supply terminal 176 with the inductor 36 therebetween and each includes a collector connected to the output terminal 32 with the output matching circuit 22 therebetween, a base connected to the collectors of the unit transistors 251 with the interstage matching circuit 21 therebetween, and an emitter connected to the ground.

To put it more concretely, the bases of the unit transistors 252 included in the power-stage amplifier 52 are connected to each other and connected to an output terminal of the interstage matching circuit 21 (or the input of the power-stage amplifier 52). The collectors of the unit transistors 252 included in the power-stage amplifier 52 are connected to each other and connected to the output terminal 32 (or the output of the power-stage amplifier 52). The emitters of the unit transistors 252 included in the power-stage amplifier 52 are connected to each other and connected to the ground. This means that the unit transistors 252 are connected in parallel.

The power-stage bias supply circuit 161 provides bias to the bases of the unit transistors 252 included in the power-stage amplifier 52.

The x-axis, the y-axis, and the z-axis are indicated in some of the accompanying drawings. The x-axis, the y-axis, and the z-axis define a three-dimensional Cartesian coordinate system. The side to which the arrow denoting the x-axis points may be hereinafter referred to as “x-axis+side”, and the opposite side may be hereinafter referred to as “x-axis−side”. The same holds for the other axes. The z-axis+side and the z-axis−side may be hereinafter also referred to as “upper side” and “lower side”, respectively. The z-axis direction may be hereinafter also referred to as “stacking direction”. A plane perpendicular to the x-axis, a plane perpendicular to the y-axis, and a plane perpendicular to the z-axis may be hereinafter referred to as “yz-plane”, “zx-plane”, and “xy-plane”, respectively. The direction in which the hands of a clock rotate as viewed from in front (i.e., from the above) is hereinafter referred to as “clockwise direction cw”. The direction opposite to that in which the hands of a clock rotate as viewed from in front (i.e., from the above) is hereinafter referred to as “counterclockwise direction ccw”.

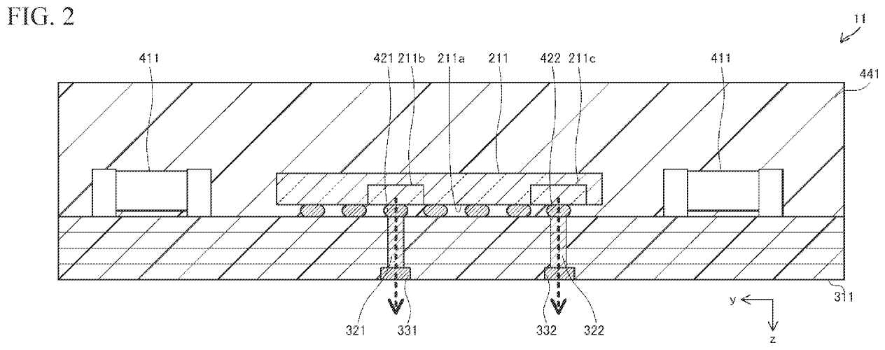

FIG. 2 is a schematic sectional view of the power amplifying device 11 taken along a line parallel to the yz-plane. Referring to FIG. 2, the power amplifying device 11 includes a semiconductor chip 211, a module substrate 311, on-board components 411, and a sealing resin 441. The semiconductor chip 211 includes a driver-stage amplifier heat generator 211b, a power-stage amplifier heat generator 211c, a stripe-type bump 421, and a stripe-type bump 422.

The module substrate 311 is, for example, a multilayer substrate including dielectric layers and wiring layers stacked on top of one another in the z-axis direction. The module substrate 311 includes a via 321, a via 322, a module back-surface electrode 331, and a module back-surface electrode 332.

The module substrate 311 is provided with the semiconductor chip 211, which is mounted on the module substrate 311 with the stripe-type bumps 421 and 422 disposed therebetween. More specifically, the semiconductor chip 211 is flip-chip mounted on the module substrate 311 and is connected to a lower surface of the module substrate 311 with the stripe-type bumps 421 and 422 disposed therebetween. An upper surface (hereinafter also referred to as a main surface 211a) of the semiconductor chip 211 is oriented toward the module substrate 311.

The module back-surface electrodes 331 and 332 are exposed at an upper surface of the module substrate 311. The module back-surface electrodes 331 and 332 are placed at the reference potential. In other words, the module back-surface electrodes 331 and 332 are connected to the ground.

The module back-surface electrodes 331 and 332 also serve as heat sinks that dissipate heat generated by the semiconductor chip 211. More specifically, the module back-surface electrodes 331 and 332 dissipate heat generated by the driver-stage amplifier heat generator 211b and heat generate by the power-stage amplifier heat generator 211c, respectively.

The vias 321 and 322 are substantially parallel to the z-axis and extend through the module substrate 311. An upper end face of the via 321 and an upper end face of the via 322 are connected to the module back-surface electrodes 331 and 332, respectively. A lower end face of the via 321 and a lower end face of the via 322 are connected to the stripe-type bumps 421 and 422, respectively.

The on-board components 411 are mounted on the lower surface of the module substrate 311. The lower surface of the module substrate 311 is overlaid with the sealing resin 441, which covers the semiconductor chip 211 and the on-board components 411.

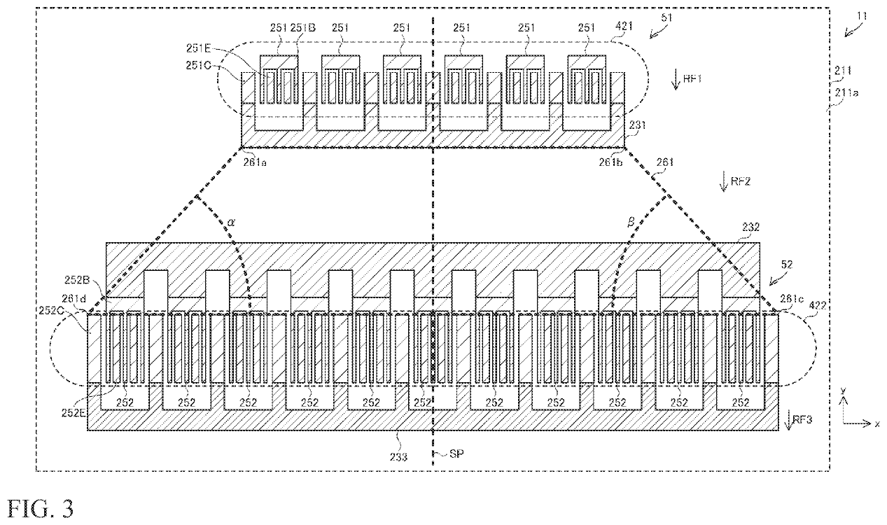

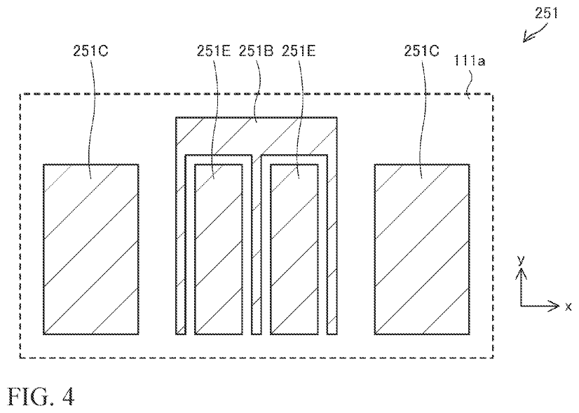

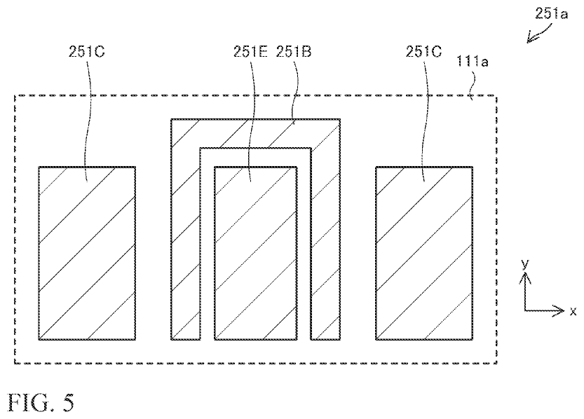

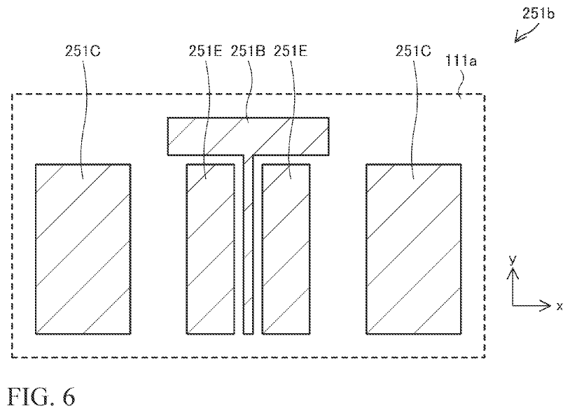

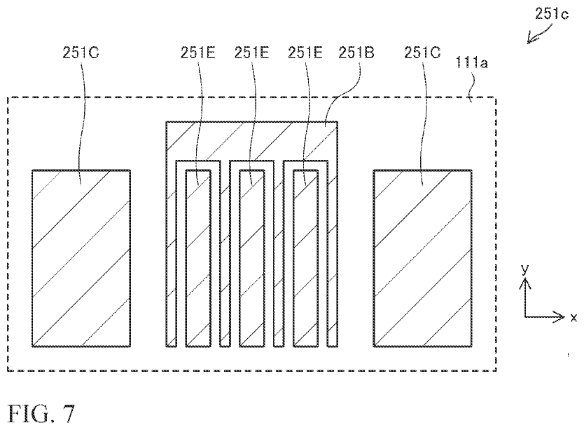

FIG. 3 is a plan view of the semiconductor chip 211 included in the power amplifying device 11, illustrating the semiconductor chip 211 viewed from the above. FIG. 4 is an enlarged plan view of one of the unit transistors 251, illustrating the unit transistor 251 viewed from the above. FIG. 5 is an enlarged plan view of a unit transistor 251a, namely, a first modification of the unit transistor 251, illustrating the unit transistor 251a viewed from the above. FIG. 6 is an enlarged plan view of a unit transistor 251b, namely, a second modification of the unit transistor 251, illustrating the unit transistor 251b viewed from the above. FIG. 7 is an enlarged plan view of a unit transistor 251c, namely, a third modification of the unit transistor 251, illustrating the unit transistor 251c viewed from the above.

As illustrated in FIGS. 2 to 7, the unit transistors 251, a matching circuit region 261, and the unit transistors 252 are located in the part closer to the main surface 211a than to the other main surface of semiconductor chip 211.

The unit transistors 251 are provided in the part closer to the main surface 211a than to the other main surface of the semiconductor chip 211 and are arranged in the x-axis direction (first direction). In the present embodiment, six unit transistors 251 are arranged in the x-axis direction and are substantially parallel to each other. In some embodiments, however, the number of unit transistors 251 in the part closer to the main surface 211a than to the other main surface of the semiconductor chip 211 is not less than two and not more than five or is not less than seven.

The unit transistor 251 illustrated in FIG. 4 includes one base electrode 251B, two collector electrodes 251C, and two emitter electrodes 251E. The unit transistors 251 are transistors of minimum size that can constitute the driver-stage amplifier 51.

The unit transistors 251 are connected in parallel. More specifically, the base electrodes 251B of the unit transistors 251 are electrically connected to each other by wiring or the like (not illustrated). The emitter electrodes 251E of the unit transistors 251 are electrically connected to each other by wiring or the like (not illustrated). The collector electrodes 251C of the unit transistors 251 are electrically connected to each other by a preceding-stage collector line 231.

The number of unit transistors 251 included in the driver-stage amplifier 51 depends on the number of base electrodes 251B. This means that the unit transistors 251 each includes only one base electrode 251B.

The unit transistors 251 each includes, in addition to the electrodes, a base part. For example, the base part includes a collector layer, a base layer on the collector layer, and an emitter layer on the base layer. The collector layer is closer than the other two layers to the lower side, and the emitter layer is closer than the other two layers to the upper side, that is, to the main surface 211a of the semiconductor chip 211. The structure of each of the unit transistors 251 is as follows. The collector electrodes 251C are electrically connected to the collector layer and are located on the upper side of the collector layer. The base electrode 251B is electrically connected to the base layer and is located on the upper side of the base layer. The emitter electrodes 251E are electrically connected to the emitter layer and are located on the upper side of the emitter layer.

When each of the unit transistors 251 is viewed from the above, the base electrode 251B and the two emitter electrodes 251E are located between the two collector electrodes 251C.

Two adjacent unit transistors 251 share one collector electrode 251C. To be more specific, the collector electrode 251C shared by two unit transistors 251 can be regarded as both the collector electrode 251C on the x-axis+side of the unit transistor 251 on the x-axis−side and the collector electrode 251C on the x-axis−side of the unit transistor 251 on the x-axis+side.

The unit transistor 251a illustrated in FIG. 5 includes one base electrode 251B, two collector electrodes 251C, and one emitter electrode 251E.

The unit transistor 251b illustrated in FIG. 6 includes one base electrode 251B, two collector electrodes 251C, and two emitter electrodes 251E. The difference between the unit transistor 251 and the unit transistor 251b is in the shape of the base electrode 251B. To put it more concretely, the base electrode 251B of the unit transistor 251b is T-shaped, whereas the base electrode 251B of the unit transistor 251 is substantially W-shaped.

The unit transistor 251c illustrated in FIG. 7 includes one base electrode 251B, two collector electrodes 251C, and three emitter electrodes 251E. The differences between the unit transistor 251 and the unit transistor 251c are in the shape of the base electrode 251B and the number of emitter electrodes 251E.

The emitter electrodes 251E of the unit transistors 251 are located within the stripe-type bump 421 when the semiconductor chip 211 is viewed in plan in the z-axis direction (third direction).

The stripe-type bump 421 in the present embodiment extends in the x-axis direction and is wider than each of the unit transistors 251; that is, the dimension of the stripe-type bump 421 in the y-axis direction (second direction) is greater than the dimension of each of the unit transistors 251 in the direction concerned. The unit transistors 251 are located on the inner side with respect to the outline of the stripe-type bump 421 when the semiconductor chip 211 is viewed in plan in the z-axis direction.

The stripe-type bump 421 is electrically connected to the emitter electrodes 251E of the unit transistors 251. The stripe-type bump 421 in the present embodiment is electrically connected to the emitter electrodes 251E of the unit transistors 251 by an emitter line (not illustrated) disposed on the upper side of the emitter electrodes 251E.

The stripe-type bump 421 is electrically connected to the module back-surface electrode 331 with by the via 321 extending therebetween (see FIG. 2). For example, the emitter layers of the unit transistors 251 constitute the driver-stage amplifier heat generator 211b.

This structure promotes the transfer of heat from the emitter layers of the unit transistors 251 such that the heat is transferred to the module back-surface electrode 331 through the emitter electrodes 251E, the stripe-type bump 421, and the via 321. The heat transferred from the driver-stage amplifier heat generator 211b is then dissipated through the module back-surface electrode 331.

The unit transistors 252 are provided in the part closer to the main surface 211a than to the other main surface of the semiconductor chip 211 (see FIG. 3). The unit transistors 252 are located on the y-axis−side with respect to the unit transistors 251 and are arranged in the x-axis direction. In the present embodiment, eleven unit transistors 252 are provided. In some embodiments, however, the number of unit transistors 252 in the part closer to the main surface 211a than to the other main surface of the semiconductor chip 211 is not less than two and not more than ten or is not less than twelve.

The unit transistors 252 each includes one base electrode 252B, two collector electrodes 252C, and two emitter electrodes 252E. The unit transistors 252 are transistors of minimum size that can constitute the power-stage amplifier 52.

The unit transistors 252 are connected in parallel. More specifically, the base electrodes 252B of the unit transistors 252 are electrically connected to each other by a subsequent-stage base line 232. The emitter electrodes 252E of the unit transistors 252 are electrically connected to each other by wiring or the like (not illustrated). The collector electrodes 252C of the unit transistors 252 are electrically connected to each other by a subsequent-stage collector line 233.

The number of unit transistors 252 included in the power-stage amplifier 52 depends on the number of base electrodes 252B. This means that the unit transistors 252 each includes only one base electrode 252B.

The unit transistors 252 each includes, in addition to the electrodes, a base part. For example, the base part includes a collector layer, a base layer on the collector layer, and an emitter layer on the base layer. The collector layer is closer than the other two layers to the lower side, and the emitter layer is closer than the other two layers to the upper side, that is, to the main surface 211a of the semiconductor chip 211. The structure of each of the unit transistors 252 is as follows. The collector electrodes 252C are electrically connected to the collector layer and are located on the upper side of the collector layer. The base electrode 252B is electrically connected to the base layer and is located on the upper side of the base layer. The emitter electrodes 252E are electrically connected to the emitter layer and are located on the upper side of the emitter layer.

Each of the unit transistors 251 is smaller than each of the unit transistors 252. For example, the size of each of the unit transistors 251 is the cross-sectional area of the emitter electrode 251E or, more specifically, the area of cross section substantially perpendicular to a flow of emitter current. In the present embodiment, the sum of the areas of two emitter electrodes 251E of each of the unit transistors 251 included in the semiconductor chip 211 viewed in plan in the z-axis direction is regarded as the size of each of the unit transistors 251.

Likewise, the sum of the areas of two emitter electrodes 252E of each of the unit transistors 252 included in the semiconductor chip 211 viewed in plan in the z-axis direction is regarded as the size of each of the unit transistors 252.

Although each of the unit transistors 252 is not equal in size to each of the unit transistors 251, each of the unit transistors 252 is geometrically similar to each of the unit transistors 251. It is not required that each of the unit transistors 252 be geometrically similar to each of the unit transistors 251. For example, each of the unit transistors 252 may be geometrically similar to the unit transistor 251a, 251b, or 251c.

The stripe-type bump 422 extends in the x-axis direction and is wider than each of the unit transistors 252; that is, the dimension of the stripe-type bump 422 in the y-axis direction is greater than the dimension of each of the unit transistors 252 in the direction concerned. The unit transistors 252 are located on the inner side with respect to the outline of the stripe-type bump 422 when the semiconductor chip 211 is viewed in plan in the z-axis direction.

The stripe-type bump 422 is electrically connected to the emitter electrodes 252E of the unit transistors 252 by an emitter line (not illustrated) disposed on the upper side of the emitter electrodes 252E.

The stripe-type bump 422 is electrically connected to the module back-surface electrode 332 by the via 322 extending therebetween (see FIG. 2). For example, the emitter layers of the unit transistors 252 constitute the power-stage amplifier heat generator 211c.

This structure promotes the transfer of heat from the emitter layers of the unit transistors 252 such that the heat is transferred to the module back-surface electrode 332 through the emitter electrodes 252E, the stripe-type bump 422, and the via 322. The heat transferred from the power-stage amplifier heat generator 211c is then dissipated through the module back-surface electrode 332.

The interstage matching circuit 21 is electrically connected between the preceding-stage collector line 231 and the subsequent-stage base line 232. One or more of the components (not illustrated) constituting the interstage matching circuit 21 are disposed in the matching circuit region 261 located between the unit transistors 251 and the unit transistors 252.

For example, a row of the unit transistors 251, a row of the unit transistors 252, and the matching circuit region 261 are each arranged symmetrically with respect to a symmetry plane SP, which is parallel to the yz-plane.

The region populated with the unit transistors 251 is smaller in dimension in the x-axis direction than the region populated with the unit transistors 252. Thus, the matching circuit region 261 has a trapezoidal shape having a shorter base on the y-axis+side and a longer base on the y-axis−side.

The shorter base on the y-axis+side of the matching circuit region 261 connects a vertex 261a and a vertex 261b to each other. The vertex 261a is located at one of the corners of the preceding-stage collector line 231 or, more specifically, the corner on the x-axis−side and y-axis−side. The vertex 261b is located at one of the corners of the preceding-stage collector line 231 or, more specifically, the corner on the x-axis+side and y-axis−side. Each of the corners may be an end portion; that is, it is not required that two lines meet at the corner to form an angle. To put it more concretely, when the preceding-stage collector line 231 does not have a corner on the x-axis−side (or the x-axis+side) and the y-axis−side; that is, when the periphery of the end portion on the side concerned is curved, the outermost point on the periphery of the end portion is regarded as the vertex 261a or the vertex 261b.

The longer base on the y-axis−side of the matching circuit region 261 connects a vertex 261c and a vertex 261d to each other. The vertex 261c is at the corner on the x-axis+side and the y-axis+side of the outermost collector electrode 252C connected to the collector layer of the unit transistor 252 that is located on the x-axis+side with respect to the other unit transistors 252. The vertex 261d is at the corner on the x-axis−side and the y-axis+side of the outermost collector electrode 252C connected to the collector layer of the unit transistor 252 that is located on the x-axis−side with respect to the other unit transistors 252. Each of the corners may be an end portion; that is, it is not required that two lines meet at the corner to form an angle. To put it more concretely, when the collector electrode 252C concerned does not have a corner on the x-axis+side (or the x-axis−side) and the y-axis+side; that is, when the periphery of the end portion on the side concerned is curved, the outermost point on the periphery of the end portion is regarded as the vertex 261c or the vertex 261d.

This means that the matching circuit region 261 fits on the trapezoidal shape defined by the vertices 261a, 261b, 261c, and 261d. With the matching circuit region 261 being trapezoidal in shape, the angles formed at two opposite ends of the longer base located on the y-axis−side are respectively denoted by α and β and are each preferably not less than 45° and not more than 90°.

This point is described below in more detail. The power-stage amplifier 52 is sized in accordance with the output power of the power amplifier circuit 101. Although the driver-stage amplifier 51 is sized with consideration given to the gain of the power-stage amplifier 52, the power-stage amplifier 52 is generally much larger than the driver-stage amplifier 51.

If each of the unit transistors 251 is equal in size to each of the unit transistors 252, the region populated with the unit transistors 252 of the power-stage amplifier 52 would be much greater in dimension in the x-axis direction than the region populated with the unit transistors 251 of the driver-stage amplifier 51.

In this case, the angles α and β formed in the matching circuit region 261 would be smaller than the respective angles in FIG. 3, and the distance between the row of the unit transistors 251 and the row of the unit transistors 252 would vary greatly.

That is, there would be a large difference between the unit transistors 251 and 252 close to the symmetry plane SP and the distance between the unit transistors 251 and 252 at the end on the x-axis+side or the x-axis−side. This would lead to a large phase difference between a signal being transmitted in close proximity to the symmetry plane SP and a signal being transmitted in close proximity to the end on the x-axis+side or the x-axis−side such that it would be difficult to provide impedance matching.

As a workaround, each of the unit transistors 251 is made smaller than each of the unit transistors 252. Although the smallness of the unit transistors 251 can lead to a decrease in the output power of the driver-stage amplifier 51, the unit transistors 251 are increased in number to compensate for the decrease. Accordingly, the dimension of the region populated with the unit transistors 251 of the driver-stage amplifier 51 in the x-axis direction is increased. The angles α and β are increased correspondingly.

This leads to a decrease in the phase difference between a signal being transmitted in close proximity to the symmetry plane SP and a signal being transmitted in close proximity to the end on the x-axis+side or the x-axis−side and, as a result, ease of impedance matching is achieved.

The heat generators (the emitter layers connected to the emitter electrodes 251E) are each reduced in size (in the y-axis direction), with a view to making each of the unit transistors 251 smaller than each of the unit transistors 252. Instead, the heat generators (arranged in the x-axis direction) may be increased in number.

More specifically, the gross area calculated by adding up the areas of the emitter layers of the unit transistors 251 is adjusted in accordance with the output power demanded of the driver-stage amplifier 51. When the unit transistors 251 constituting the driver-stage amplifier 51 are reduced in size, the unit transistor 251 need to be increased in number in order to make up a shortfall in the predetermined required gain of the driver-stage amplifier 51.

As mentioned above, the heat generators are increased in number to offset the decrease in the areas of the heat generators. In this case, the heat generators are more dispersedly located in the region in which the stripe-type bump 421 extends. The overall heat production of the driver-stage amplifier 51 is distributed among the dispersedly located heat generators, each of which generates a small amount of heat. As a result, the degree of heat concentration is reduced, and the heat generated in the driver-stage amplifier 51 is released in an efficient manner. This configuration reduces the degree of temperature rise in the heat generators and, by extension, the degree of temperature rise in the unit transistors 251. Relatively high output power is demanded of the driver-stage amplifier 51 acting as a class-A amplifier in particular; nevertheless, the configuration described above enables the power amplifying device 11 including the driver-stage amplifier 51 to operate without necessarily significant deterioration of the amplification characteristics and without necessarily significant impairment of reliability.

As mentioned above, the power-stage amplifier 52 would be much greater in dimension in the x-axis direction than the driver-stage amplifier 51 if each of the unit transistors 252 is made equal in size to each of the unit transistors 251 without necessarily compromising the required output power (size) of the power-stage amplifier 52. With this in view, each of the unit transistors 252 is made larger than each of the unit transistors 251 so that the footprint of the power-stage amplifier 52 in the x-axis direction will not be excessively increased. The power amplifying device 11 may thus be compact in size.

### Second Embodiment

The following describes a power amplifying device 12 according to a second embodiment. Redundant description of features common to the first embodiment and another embodiment will be omitted. The second embodiment and subsequent embodiments will be described with regard to their distinctive features only. This is particularly true for similar effects; that is, not every embodiment refers to such effects associated with similar features.

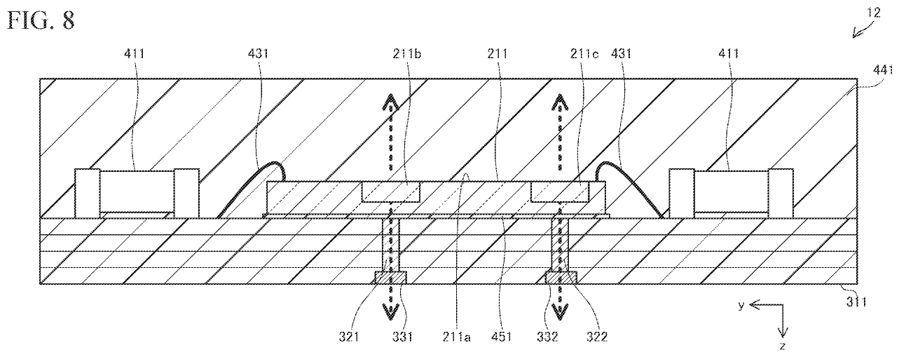

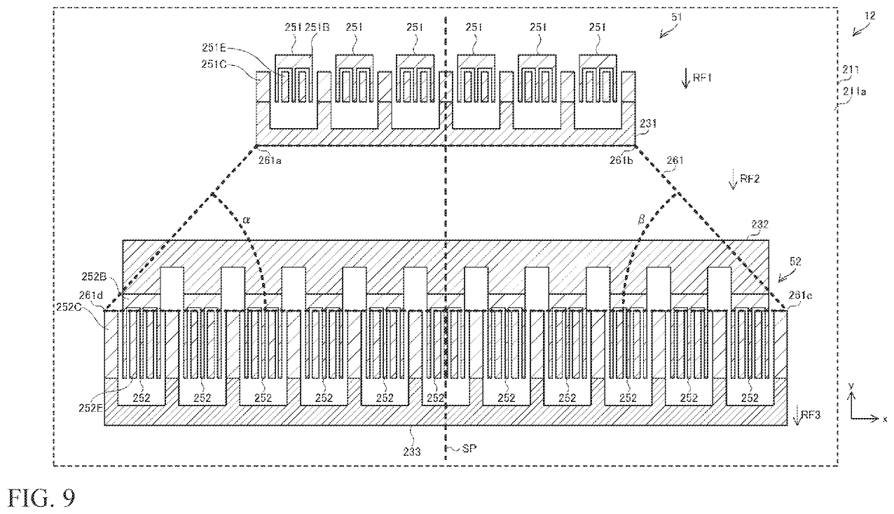

FIG. 8 is a schematic sectional view of the power amplifying device 12 taken along a line parallel to the yz-plane. FIG. 9 is a plan view of the semiconductor chip 211 included in the power amplifying device 12, illustrating the semiconductor chip 211 viewed from the above. The power amplifying device 12 according to the second embodiment (see FIGS. 8 and 9) differs from the power amplifying device 11 according to the first embodiment in that the semiconductor chip 211 and the module substrate 311 are electrically connected to each other by bonding wires.

The semiconductor chip 211 of the power amplifying device 12 is mounted on the module substrate 311 with the main surface 211a oriented downward and an adhesive layer 451 disposed between the semiconductor chip 211 and the module substrate 311. The semiconductor chip 211 and the module substrate 311 are electrically connected to each other by bonding wires 431.

The module back-surface electrode 331 and the via 321 are located within the driver-stage amplifier heat generator 211b when the power amplifying device 12 is viewed in plan in the z-axis direction.

This structure promotes the transfer of heat from the driver-stage amplifier heat generator 211b such that the heat is transferred to the module back-surface electrode 331 through the semiconductor chip 211, the adhesive layer 451, and the via 321. The heat transferred from the driver-stage amplifier heat generator 211b is then dissipated through the module back-surface electrode 331.

The module back-surface electrode 332 and the via 322 are located within the power-stage amplifier heat generator 211c when the power amplifying device 12 is viewed in plan in the z-axis direction.

This structure promotes the transfer of heat from the power-stage amplifier heat generator 211c such that the heat is transferred to the module back-surface electrode 332 through the semiconductor chip 211, the adhesive layer 451, and the via 322. The heat transferred from the power-stage amplifier heat generator 211c is then dissipated through the module back-surface electrode 332.

The heat generated by the driver-stage amplifier heat generator 211b and the heat generate by the power-stage amplifier heat generator 211c are also dissipated through the sealing resin 441.

### Third Embodiment

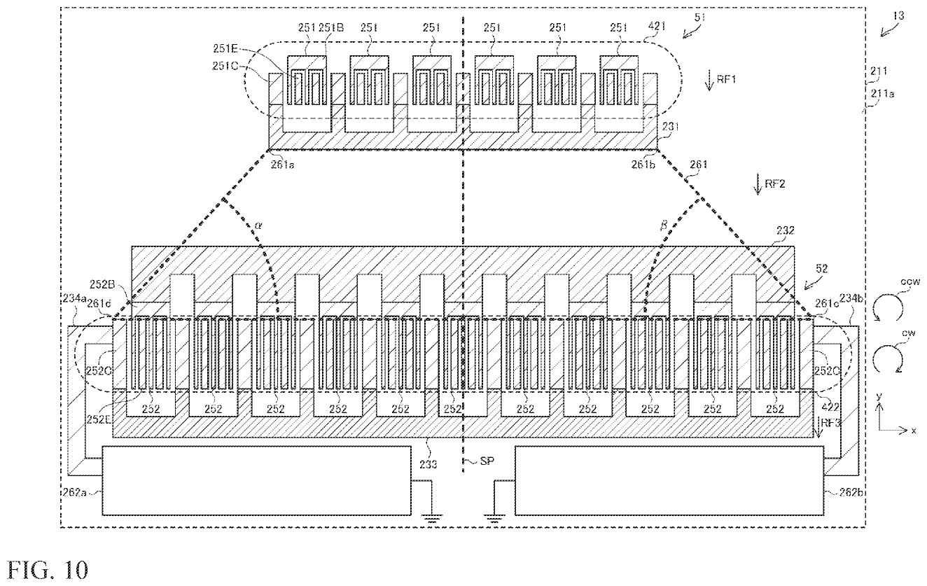

The following describes a power amplifying device 13 according to a third embodiment. FIG. 10 is a plan view of the semiconductor chip 211 included in the power amplifying device 13, illustrating the semiconductor chip 211 viewed from the above. The power amplifying device 13 according to the third embodiment (see FIG. 10) differs from the power amplifying device 11 according to the first embodiment in that the power-stage amplifier 52 acts as a class-F amplifier or an inverse class-F amplifier.

The unit transistors 252 of the power amplifying device 13 are designed to operate in class-F or inverse class-F. This point is described below in more detail. The power-stage amplifier 52 ideally acts as a class-F amplifier or an inverse class-F amplifier when the load impedance of the power-stage amplifier 52 is controlled to satisfy the following conditions: there is no instantaneous voltage across the amplifier when there is an instantaneous current flowing through the amplifier; and there is no instantaneous current flowing through the amplifier when there is an instantaneous voltage across the amplifier.

The requirement pertaining to class-F operation of the power-stage amplifier 52 is as follows: the output matching circuit 22 needs to be designed so that the load impedance seen from an output terminal of the power-stage amplifier 52 is a short circuit at even harmonics and an open circuit at odd harmonics.

The requirement pertaining to inverse class-F operation of the power-stage amplifier 52 is as follows: the output matching circuit 22 needs to be designed so that the load impedance seen from the output terminal of the power-stage amplifier 52 is an open circuit at even harmonics and a short circuit at odd harmonics.

In the present embodiment, components serving as inductors in the output matching circuit 22 and components serving as capacitors in the output matching circuit 22 are disposed in close proximity to the subsequent-stage collector line 233 connected to the collector electrodes 252C of the unit transistors 252 so that the load impedance in a frequency range of harmonics can be controlled.

More specifically, an inductor electrode 234a and an inductor electrode 234b are disposed on the x-axis−side and the x-axis+side, respectively, of the row of the unit transistors 252.

The inductor electrode 234a has a first end and a second end. The first end of the inductor electrode 234a is connected to an end portion on the x-axis−side of the outermost collector electrode 252C connected to the collector layer of the unit transistor 252 that is located on the x-axis−side with respect to the other unit transistors 252. The inductor electrode 234a is wound in the counterclockwise direction ccw in the xy-plane, where the number of winding turns formed between the first end and the second end is more than or equal to ¼ and less than ¾.

The inductor electrode 234b has a first end and a second end. The first end of the inductor electrode 234b is connected to an end portion on the x-axis+side of the outermost collector electrode 252C connected to the collector layer of the unit transistor 252 that is located on the x-axis+side with respect to the other unit transistors 252. The inductor electrode 234b is wound in the clockwise direction cw in the xy-plane, where the number of winding turns formed between the first end and the second end is more than or equal to ¼ and less than ¾.

The inductor electrodes 234a and 234b are components serving as inductors in the output matching circuit 22. The adjustment of the inductance of the inductors is made by changing, for example, the shape and length of a wiring pattern.

A capacitor region 262a and a capacitor region 262b are located on the y-axis−side with respect to the subsequent-stage collector line 233 and extend along the x-axis. The capacitor region 262b is located on the x-axis +side with respect to the capacitor region 262a. Components serving as capacitors in the output matching circuit 22 are disposed in the capacitor regions 262a and 262b.

An end portion on the x-axis−side of the capacitor region 262a is connected to the second end of the inductor electrode 234a, and an end portion on the x-axis+side of the capacitor region 262a is connected to the ground.

An end portion on the x-axis−side of the capacitor region 262b is connected to the ground, and an end portion on the x-axis+side of the capacitor region 262b is connected to the second end of the inductor electrode 234b.

### Fourth Embodiment

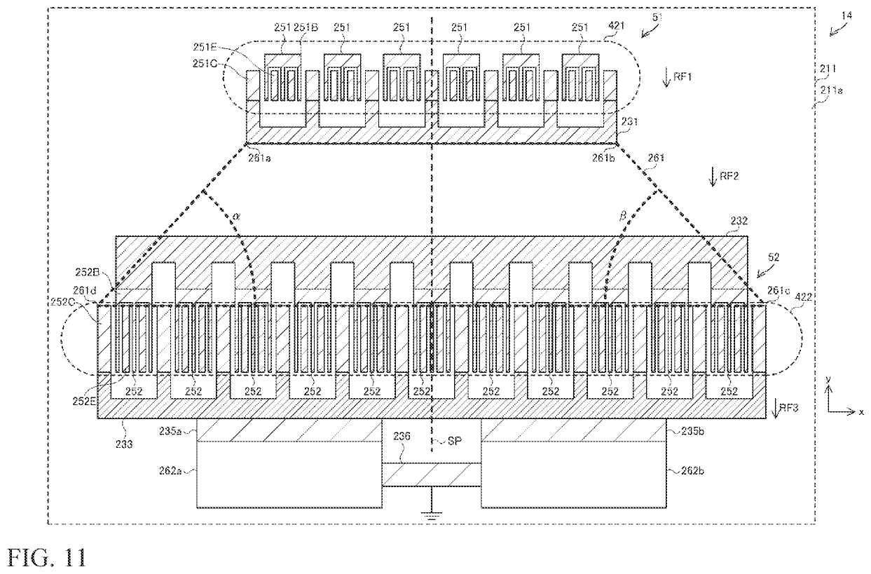

The following describes a power amplifying device 14 according to a fourth embodiment. FIG. 11 is a plan view of the semiconductor chip 211 included in the power amplifying device 14, illustrating the semiconductor chip 211 viewed from the above. The difference between the power amplifying device 14 according to the fourth embodiment (see FIG. 11) and the power amplifying device 13 according to the third embodiment is in the shape of the inductor electrodes.

The power amplifying device 14 includes an inductor electrode 235a and an inductor electrode 235b, which are disposed on the y-axis−side with respect to the subsequent-stage collector line 233 and extend along the x-axis. The inductor electrode 235b is disposed on the x-axis+side with respect to the inductor electrode 235a.

When viewed from the above, the inductor electrodes 235a and 235b are rectangular in shape and each has long sides extending in the x-axis direction and short sides extending in the y-axis direction. An end portion on the y-axis+side of the inductor electrode 235a and an end portion on the y-axis+side of the inductor electrode 235b are connected to an end portion on the y-axis−side of the subsequent-stage collector line 233.

The capacitor region 262a is located on the y-axis−side of the inductor electrode 235a, and the capacitor region 262b is located on the y-axis−side of the inductor electrode 235b.

An end portion on the y-axis+side of the capacitor region 262a is connected to an end portion on the y-axis−side of the inductor electrode 235a, and an end portion on the y-axis+side of the capacitor region 262b is connected to an end portion on the y-axis−side of the inductor electrode 235b.

The capacitor region 262a and the capacitor region 262b are located with an inductor electrode 236 disposed therebetween. When viewed from the above, the inductor electrodes 236 is rectangular in shape and has long sides extending in the x-axis direction and short sides extending in the y-axis direction.

The inductor electrode 236 has a first end and a second end. The first end of the inductor electrode 236 is connected to an end portion on the x-axis+side of the capacitor region 262a. The second end of the inductor electrode 236 is connected to an end portion on the x-axis−side of the capacitor region 262b. The midpoint between the first end and the second end of the inductor electrode 236 is connected to the ground.

The inductor electrodes 235a, 235b, and 236 are components serving as inductors in the output matching circuit 22. The adjustment of the inductance of the inductors is made by changing, for example, the shape and length of the wiring pattern.

As mentioned above in relation to the power amplifying devices 11 to 14, the unit transistors 251 are arranged in a straight line along the x-axis. In some embodiments, however, the unit transistors 251 are arranged differently in the part closer to the main surface 211a than to the other main surface of the semiconductor chip 211.

As mentioned above in relation to the power amplifying devices 11 to 14, the unit transistors 252 are arranged in a straight line along the x-axis. In some embodiments, however, the unit transistors 252 are arranged differently in the part closer to the main surface 211a than to the other main surface of the semiconductor chip 211.

As mentioned above in relation to the power amplifying devices 11 to 14, the module back-surface electrodes 331 and 332 are exposed at the upper surface of the module substrate 311. In some embodiments, however, the module back-surface electrodes 331 and 332 are not exposed at the upper surface of the module substrate 311.

Embodiments that have been described so far are presented as examples of the present disclosure. The threshold voltage (Vbe) between the base and the emitter typically drops when the transistors in operation generate heat and rise in temperature. This causes an increase in base current regardless of the fact that the base bias voltage applied to the base is kept constant. The resultant increase in collector current translates into an increase in collector dissipation and, by extension, into a decrease in transistor gain.

The unit transistors 251 of each of the power amplifying devices 11, 12, 13, and 14 are connected in parallel and configured to amplify the signal RF1 and to output the resultant signal. The unit transistors 252 of each of the power amplifying devices 11, 12, 13, and 14 are connected in parallel and configured to amplify the amplified signal RF2 output by the unit transistors 251 and to output the resultant signal. Each of the unit transistors 251 is smaller than each of the unit transistors 252.

Instead of being equal in size to each of the unit transistors 252, each of the unit transistors 251 is made smaller than each of the unit transistors 252 such that the unit transistors 251 can be increased in number without necessarily any change in the overall size of the driver-stage amplifier 51. The overall heat production of the driver-stage amplifier 51 is distributed among the dispersedly located unit transistors 251, each of which generates a small amount of heat. As a result, the degree of heat concentration is reduced. Accordingly, the degree of temperature rise in the unit transistors 251 is reduced. This offers an advantage in that the unit transistors 251 can output the high-power amplified signal RF2 without necessarily decreases in gain. Furthermore, the amount of deterioration caused by heat is reduced so that the driver-stage amplifier 51 can operate without necessarily significant impairment of reliability. The power-stage amplifier 52 is generally larger than the driver-stage amplifier 51. If each of the unit transistors 252 is made equal in size to each of the unit transistors 251, a greater number of unit transistors 252 would be required. The power-stage amplifier 52 in which a greater number of unit transistors 252 are dispersedly located is large in size. As a workaround, each of the unit transistors 252 is made larger than each of the unit transistors 251. This eliminates the need to increase the number of unit transistors 252 such that there is not much increase in the size of the power-stage amplifier 52. Thus, the power amplifying device designed as above is operable without necessarily significant deterioration of amplification characteristics and without necessarily significant impairment of reliability and is compact in size.

The unit transistors 251 of each of the power amplifying devices 11, 12, 13, and 14 are designed to operate in class-A.

As an amplifier for large-capacity communication under the standardization of a transmission bandwidth of up to 200 MHz, the power amplifying device designed as above has good linearity for signals in a wide frequency band. When the base bias voltage applied to the transistors is high enough to cause the driver-stage amplifier 51 to act as a class-A amplifier, the current density is increased and causes heating. With this in view, each of the unit transistors 251 is made smaller than each of the unit transistors 252 so that the degree of heat concentration is reduced. Accordingly, the degree of temperature rise in the unit transistors 251 is reduced.

The unit transistors 252 of each of the power amplifying devices 13 and 14 are designed to operate in class-F or inverse class-F.

This feature contributes to the enhanced efficiency of the unit transistors 252.

The main surface 211a of the semiconductor chip 211 of each of the power amplifying devices 11, 13, and 14 is parallel to a plane defined by the x-axis direction and the y-axis direction that forms an angle with the x-axis direction. The unit transistors 251 are arranged in the x-axis direction. The stripe-type bump 421 is electrically connected to the emitter electrodes 251E of the unit transistors 251. The emitter electrodes 251E are located within the stripe-type bump 421 when the semiconductor chip 211 is viewed in plan in the direction of the z-axis that forms an angle with both the x-axis and the y-axis.

This feature enables a decrease in the distance between the row of the unit transistors 251 and the stripe-type bump 421 such that heat generated in the emitter layers connected to the emitter electrodes 251E is speedily transferred to the stripe-type bump 421. The stripe-type bump 421 is strip-shaped and can thus be large in size. An increase in the size of the stripe-type bump 421 translates into an increase in the heat capacity of the stripe-type bump 421. Accordingly, the degree of temperature rise in the unit transistors 251 can be reduced in an efficient manner.

The module substrate 311 of each of the power amplifying devices 11, 13, and 14 is provided with the semiconductor chip 211, which is mounted on the module substrate 311 with the stripe-type bumps 421 and 421 disposed therebetween. The module substrate 311 includes the via 321 and the module back-surface electrode 331. The via 321 extends through at least part of the module substrate 311. The module back-surface electrode 331 is electrically connected to the stripe-type bump 421 by the via 321.

Heat in the stripe-type bump 421 can thus be speedily transferred to the module back-surface electrode 331 through the via 321 such that the degree of temperature rise in the stripe-type bump 421 is reduced. Accordingly, the degree of temperature rise in the unit transistors 251 is reduced in a more efficient manner.

The embodiments above have been described to facilitate the understanding of the present disclosure and should not be construed as limiting the scope of the present disclosure. The present disclosure may be altered and/or improved without necessarily departing from the spirit of the present disclosure and embraces equivalents thereof. That is, the embodiments with design changes made as appropriate by those skilled in the art fall within the scope of the present disclosure as long as the features of the present disclosure are involved. For example, constituent components in the embodiments above and the arrangement, materials, conditions, shapes, and sizes of the constituent components are not limited to those mentioned in the description and may be changed as appropriate. The embodiments described herein are merely examples. Needless to say, partial replacements or combinations of configurations illustrated in different embodiments are possible and fall within the scope of the present disclosure as long as the features of the present disclosure are involved.

<1>

A power amplifying device, including:
first unit transistors connected in parallel and configured to amplify a radio frequency signal and to output a resultant signal; and
second unit transistors connected in parallel and configured to amplify the signal output by the first unit transistors and to output a resultant signal, each of the first unit transistors being smaller than each of the second unit transistors.

<2>

The power amplifying device according to <1>, wherein the first unit transistors operate in class-A.

<3>

The power amplifying device according to <1> or <2>, wherein the second unit transistors operate in class-F or inverse class-F.

<4>

The power amplifying device according to any one of <1> to <3>, further including:
a semiconductor chip having a main surface parallel to a plane defined by a first direction and a second direction that forms an angle with the first direction, the main surface being populated with the first unit transistors arranged in the first direction; and
a stripe-type bump electrically connected to emitter electrodes of the first unit transistors, the emitter electrodes being located within the stripe-type bump when the semiconductor chip is viewed in plan in a third direction that forms an angle with each of the first direction and the second direction.

<5>

The power amplifying device according to <4>, further including a substrate, the semiconductor chip being mounted on the substrate with the stripe-type bump disposed therebetween, wherein
the substrate includes
   a via extending through at least part of the substrate, and
   an electrode electrically connected to the stripe-bump by the via.

What is claimed is:

1. A power amplifying device comprising:
a plurality of first unit transistors connected in parallel with each other, and configured to amplify a radio frequency signal and to output a first resultant signal; and
a plurality of second unit transistors connected in parallel with each other, and configured to amplify the resultant signal output by the first unit transistors and to output a second resultant signal,
wherein each of the first unit transistors is smaller than each of the second unit transistors.

2. The power amplifying device according to claim 1, wherein the first unit transistors are class-A transistors.

3. The power amplifying device according to claim 1, wherein the second unit transistors are class-F or inverse class-F transistors.

4. The power amplifying device according to claim 1, further comprising:
a semiconductor chip having a main surface parallel populated with the first unit transistors arranged in a first direction in a plane of the semiconductor chip; and
a stripe-type bump electrically connected to emitter electrodes of the first unit transistors, the emitter electrodes being located within the stripe-type bump in a plan view of the semiconductor chip.

5. The power amplifying device according to claim 4, further comprising a substrate, the semiconductor chip being mounted on the substrate with the stripe-type bump disposed therebetween,
wherein the substrate comprises:
a via extending through at least part of the substrate, and
an electrode electrically connected to the stripe-bump by the via.
